(19) United States
(12) Patent Application Publication
(10) Pub. No.: US 2010/0264489 A1
(43) Pub. Date: Oct. 21, 2010

(54) SEMICONDUCTOR DEVICE

(75) Inventors: Hiroshi OHTA, Hyogo-ken (JP); Wataru SAITO, Kanagawa-ken (JP); Syotaro ONO, Kanagawa-ken (JP); Munehisa YABUZAKI, Kanagawa-ken (JP); Nana HATANO, Kanagawa-ken (JP); Miho WATANABE, Tokyo (JP)

Correspondence Address: PATTERSON & SHERIDAN, L.L.P., 3040 POST OAK BOULEVARD, SUITE 1500, HOUSTON, TX, 77056, US

(73) Assignee: KABUSHIKI KAISHA TOSHIBA, Tokyo (JP)

(21) Appl. No.: 12/719,475

(22) Filed: Mar. 8, 2010

(30) Foreign Application Priority Data
Apr. 16, 2009 (JP) 2009-100338

(51) Int. Cl. H01L 27/06; H01L 29/78

(52) U.S. Cl. 257/334; 257/339; 257/493; 257/E27.011; 257/E29.256

(57) ABSTRACT

A transistor contains a first semiconductor layer of a first conductivity type and a drift layer having a pillar structure in which a second semiconductor layer of the first conductivity type and a third semiconductor layer of a second conductivity type are alternately disposed in a direction parallel to a surface of the first semiconductor layer. The fourth semiconductor layer of the first conductivity type and the fifth semiconductor layer of the second conductivity type are alternately disposed and parallel to the drift layer. The fifth semiconductor layer has a larger amount of impurities than the fourth semiconductor layer. The sixth semiconductor layer of the first conductivity type and the seventh semiconductor layer of the second conductivity type are alternately disposed and parallel to the fourth and the fifth semiconductor layers. The seventh semiconductor layer has a smaller amount of impurities than the sixth semiconductor layer.

### CROSS REFERENCE TO RELATED APPLICATION

This application is based upon and claims the benefit of priority from the prior Japanese Patent Application No. 2009-100338, filed on Apr. 16, 2009, the entire contents of which are incorporated herein by reference.

### FIELD OF THE INVENTION

The invention relates to a power semiconductor device having a super junction structure.

### DESCRIPTION OF THE BACKGROUND

Power control semiconductor devices such as a MOSFET (metal oxide semiconductor field effect transistor) often have a structure in which a gate is provided on a surface of a semiconductor substrate, and causes a current to flow in a perpendicular direction to the surface (a vertical structure), for example. Such a semiconductor device is used as a switching element or the like.

In the MOSFET of the vertical type, on resistance depends largely on electrical resistance of a conductive layer (a drift layer). However, with the need of a sufficient withstand voltage, the MOSFET has a limitation to increase an impurity concentration in the drift layer. That is, there is a trade-off relation between increase in the withstand voltage of the element and lowering of the on resistance. As an example of a technique of forming a MOSFET to mitigate such a trade-off relation, there has been known a technique of forming a MOSFET having a super junction structure (hereinafter also referred to as a SJ structure) in which the drift layer is formed by alternately, arranging n-type pillar layers and p-type pillar layers.

In the SJ structure, amounts of charges (amounts of impurities) contained in the n-type pillar layers and in the p-type pillar layers are equal to each other. In this way, a pseudo non-doped layer is created to maintain a high withstand voltage, while the on resistance lower than a material limit can be achieved by causing a current to flow through the highly doped n-type pillar layer.

The SJ structure of the semiconductor device is often provided in a device region where a transistor is formed and in a termination region (a device periphery region) surrounding the device region where the transistor is not formed. The SJ structure is formed in the device periphery region to prevent reduction in a withstand voltage of the termination in a manufacturing process in which the device periphery region is made to have the same impurity (donor) concentration as the n-type pillar layers in the device region. Even when the SJ structure is formed in the device periphery region, a problem still exists in that the withstand voltage in the device periphery region falls below the withstand voltage in the device region, thereby causing destruction of the entire semiconductor device or reduction in reliability of the entire semiconductor device. Specifically, for example, reduction in a withstand voltage occurs because a leak current flows due to local electrical field concentration in the device periphery region, or variation in a withstand voltage occurs because hot carriers due to local electrical field concentration are trapped by an insulating film located in the device periphery region.

To address such a problem, there is a semiconductor device, for example, in which n-type pillar layers and p-type pillar layers are arranged in stripes parallel to each other, and in which a non-active region (the device periphery region) at a portion parallel to the stripes in an active region (the device region) has the n-type pillar layers with a width smaller than a width of the n-type pillar layers in the active region, and has the p-type pillar layers with a width larger than a width of p-type pillar layers in the active region. In addition, in the semiconductor device, a total amount of impurities in the p-type pillar layers is more than a total amount of impurities in the n-type pillar layers in the non-active region so that the total amounts of impurities are imbalanced. Such a semiconductor device is disclosed in Japanese Patent Application Publication No. 2005-260199.

Such semiconductor device is able to prevent electrical field concentration on a source electrode side located in the device periphery region and thus to prevent reduction in a withstand voltage that might otherwise occur on the source electrode side. However, the semiconductor device is more likely to cause electric field concentration in the device periphery region on an opposite side from the device region. In order to improve a yield rate, it is necessary to ensure the withstand voltage of the semiconductor device by causing the amounts of impurities to fall within an allowable range in spite of variations in manufacturing processes, the amounts of impurities determined by factors such as the impurity concentrations and the respective widths of the n-type pillar layers and the p-type pillar layers in the direction in which the n-type pillar layers and the p-type pillar layers are arranged in parallel. However, a sufficient yield rate cannot be achieved merely by increasing the width of the p-type pillar layers in the device periphery region.

### SUMMARY OF THE INVENTION

A semiconductor device of an aspect of the invention includes: a transistor containing a first semiconductor layer of a first conductivity type and a drift layer formed in a device region on the first semiconductor layer, the drift layer having a pillar structure in which a second semiconductor layer of the first conductivity type and a third semiconductor layer of a second conductivity type are alternately disposed in a direction parallel to a surface of the first semiconductor layer; a fourth semiconductor layer of the first conductivity type and a fifth semiconductor layer of the second conductivity type formed in a first device periphery region on the first semiconductor layer, the first device periphery region being adjacent to the device region and surrounding the device region, the fourth and the fifth semiconductor layers being alternately disposed and parallel to the drift layer, the fifth semiconductor layer having a larger amount of impurities than the fourth semiconductor layer; an electrode layer formed on the fourth and the fifth semiconductor layers with an insulating film interposed in between; and a sixth semiconductor layer of the first conductivity type and a seventh semiconductor layer of the second conductivity type formed in a second device periphery region on the first semiconductor layer, the second device periphery region being adjacent to the first device periphery region and surrounding the first device periphery region, the sixth and the seventh semiconductor layers being alternately disposed and parallel to the fourth and the fifth semiconductor layers, the seventh semiconductor layer having a smaller amount of impurities than the sixth semiconductor layer.

### BRIEF DESCRIPTION OF THE DRAWINGS

FIG. 1 is a cross-sectional view schematically showing a structure of a peripheral portion of a semiconductor device according to a first comparative example of the invention.

FIG. 2 is a plan view schematically showing a structure including a peripheral corner portion of a semiconductor device according to an embodiment of the invention.

FIGS. 3A and 3B are views schematically showing a structure of a peripheral portion of the semiconductor device according to the embodiment of the invention, in which FIG. 3A is a cross-sectional view taken along the line A-A in FIG. 2 and FIG. 3B is a cross-sectional view taken along the line B-B in FIG. 2.

FIG. 4 is a cross-sectional view schematically showing the structure of the peripheral portion of the semiconductor device according to the embodiment of the invention, which shows a state where p-type impurities are excessively doped.

FIG. 5 is a cross-sectional view schematically showing the structure of the peripheral portion of the semiconductor device according to the embodiment of the invention, which shows a state where n-type impurities are excessively doped.

FIG. 6 is a view schematically showing, as well as allowable ranges of comparative examples, an allowable range of a ratio of amounts of impurities in an n-type pillar layer and a p-type pillar layer, the allowable range ensuring a withstand voltage of the semiconductor device according to the embodiment of the invention.

FIGS. 7A to 7C are cross-sectional views schematically showing aspects of pillar layers of a semiconductor device according to a first modification of the embodiment of the invention.

FIG. 8 is a cross-sectional view schematically showing a structure of a device region of a semiconductor device according to a second modification of the embodiment of the invention.

### DETAILED DESCRIPTION OF THE INVENTION

It is a fact that a semiconductor device formed as a MOSFET having a super junction (SJ) structure reduces a withstand voltage attributable to a variation in a manufacturing process. To address the above fact, the inventors have studied a structure in which the withstand voltage is less affected by variations in the amounts of impurities in n-type pillar layers and in p-type pillar layers.

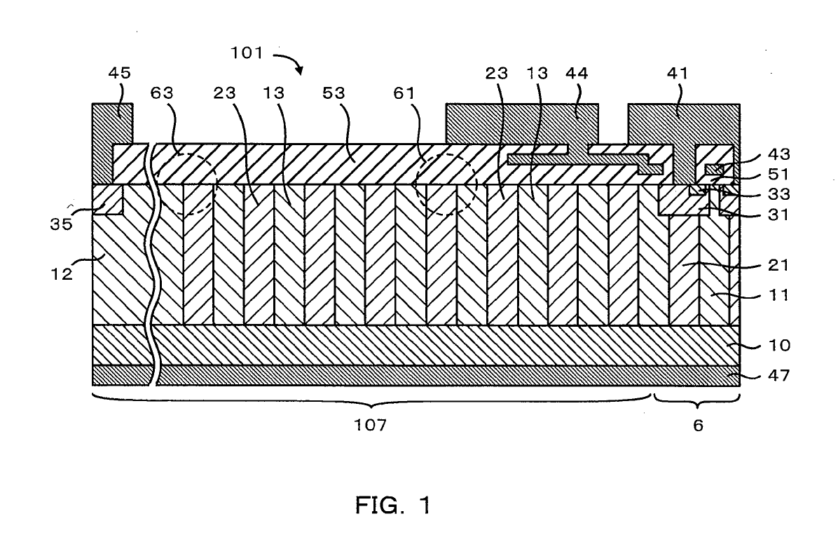

As shown in FIG. 1, a semiconductor device 101 as a first comparative example includes a device region 6. The device region 6 has an n⁺-type drain layer 10, n-type pillar layers 11 and p-type pillar layers 21 disposed on the n⁺-type drain layer 10 and alternately arranged in a direction parallel to a surface of the n⁺-type drain layer 10, a drain electrode 47 electrically connected to the n⁺-type drain layer 10, a p-type base layer 31 selectively formed in surfaces of the n-type pillar layers 11 and surfaces of the p-type pillar layers 21, an n⁺-type source layer 33 selectively formed in a surface of the p-type base layer 31, a source electrode 41 electrically connected to the p-type base layer 31 and the n⁺-type source layer 33, and a gate electrode 43 formed on the p-type base layer 31, the n⁺-type source layer 33, and the n-type pillar layers 11 with a gate insulating film 51 interposed in between. The semiconductor device 101 also includes a device periphery region 107. The device periphery region 107 surrounds the device region 6. The device periphery region 107 has n-type pillar layers 13 and p-type pillar layers 23 disposed on the n⁺-type drain layer 10 and arranged parallel to the n-type pillar layers 11 and the p-type pillar layers 21 in a way that two different conductivity types are arranged by turns. The device periphery region 107 also has a field plate electrode 44 disposed in a region close to the device region 6 and on a side opposite of the n-type pillar layers 13 and the p-type pillar layers 23 from the n⁺-type drain layer 10 with an interlayer insulating film 53 interposed in between.

The semiconductor device 101 further includes an n-type semiconductor layer 12 located on the outer side (on the opposite side from the device region 6) of the n-type pillar layers 13 and the p-type pillar layers 23 which are alternately disposed, an n⁺-type channel stopper layer 35 located in a surface of the n-type semiconductor layer 12 on an outer peripheral portion near the interlayer insulating film 53, and an equipotential ring 45 located on the n⁺-type channel stopper layer 35. The n-type semiconductor layer 12 has a similar impurity concentration to impurity concentrations of the n-type pillar layers 11, 13. The n-type pillar layers 13 and the p-type pillar layers 23 in the device periphery region 107 are arranged so as to protrude toward the equipotential ring 45 out of a plan position on an end of the field plate electrode 44 on the equipotential ring 45 side.

The n-type pillar layers 11 and the p-type pillar layers 21 are formed so as to have substantially the same amounts of impurities, i.e., so as to have the same widths and the same impurity concentrations. The width of the n-type pillars 13 is the same as the width of the n-type pillar layers 11 and the n-type pillar layers 13, 11 are formed to have the same impurity concentration. The width of the p-type pillars 23 is the same as the width of the p-type pillar layers 21 and the p-type pillar layers 23, 21 are formed to have the same impurity concentration. The pitch between each n-type pillar layer 13 and each p-type pillar layer 23 in the direction of arrangement is the same as the pitch between each n-type pillar layer 11 and each p-type pillar layer 21 in the direction of arrangement. That is, the amount of impurities in the n-type pillar layers 13 in the device periphery region 107 is the same as the amount of impurities in the n-type pillar layers 11 in the device region 6. Moreover, the amount of impurities in the p-type pillar layers 23 in the device periphery region 107 is the same as the amount of impurities in the p-type pillar layers 21 in the device region 6. Here, the width of the pillar layer is equivalent to a dimension extending in the direction the pillar layers are arranged when the cross section of the pillar layer in the direction of arrangement is approximated by a rectangle, which is a value corresponding to a cross-sectional area when the height is constant. In the case of a trench (a groove) used for the pillar layer, the width of the pillar layer corresponds to a width after an aperture is buried. Meanwhile, the pitch in the direction of arrangement is equivalent to a distance between the closest two n-type pillar layers or a distance between the closest two p-type pillar layers.

Although illustration is omitted, the n-type pillar layers 11, 13 and the p-type pillar layers 21, 23 have strip shapes having a substantially uniform width and extend in a perpendicular direction relative to a sheet surface of FIG. 1.

The semiconductor device 101 can be fabricated in any of several schemes. For example, when fabricating the semiconductor device 101 in accordance with a trench filling method, it is difficult to form trenches for the p-type pillar layers 21, 23 to desired aperture dimensions without variations as compared to the n-type pillar layers 11, 13. Moreover, since the n-type pillar layers 11, 13 and the p-type pillar layers 21, 23 are fabricated by separate epitaxial growth processes. Accordingly, it is difficult to achieve exactly the same impurity concentrations. Meanwhile, even if the semiconductor device 101 is to be fabricated by means of repeating ion implantation and filling growth, for example, it is still possible to prevent variations in dosage amounts or variations in dimensions. The inventors have studied relations between the variations and the withstand voltages in detail.

As a result, the inventors have found that when the amount of impurities in the n-type pillar layers 13 in the semiconductor device 101 is increased, i.e., when there is a variation such that the width of the n-type pillar layers 13 is relatively increased, the reduction in the withstand voltage attributable to a leak current caused by local electrical field concentration occurs, or degradation in reliability due to hot carriers occurs in the vicinity of an interface (a breakdown region 61) between the interlayer insulating film 53 and each of the n-type and p-type pillar layers 13, 23 near the end of the field plate electrode 44 on the equipotential ring 45 side.

In addition, the inventors have also found that when the amount of impurities in the p-type pillar layers 23 is increased, i.e., when there is a variation such that the width of the p-type pillar layers 23 is relatively increased, the reduction in the withstand voltage attributable to a leak current caused by local electrical field concentration occurs, or degradation in reliability due to hot carriers occurs in the vicinity of an interface (a breakdown region 63) between the interlayer insulating film 53 and the p-type pillar layer 23 located closest to the equipotential ring 45.

From the above-described results, the inventors have reached the invention by investigating the electrical field concentration that occurs in the vicinity of the interface between the interlayer insulating film 53 and each of the n-type and p-type pillar layers 13, 23 near the end of the field plate electrode 44 on the equipotential ring 45 side and the electrical field concentration that occurs in the vicinity of the interface between the interlayer insulating film 53 and the p-type pillar layer 23 located closest to the equipotential ring 45.

Although illustration is omitted, a second comparative example representing another modification of the semiconductor device 101 has also been studied. The second comparative example has a standard structure (a design structure) in which the amounts of impurities in the n-type pillar layers 11 and the p-type pillar layers 21 in the device region 6 are set substantially equal while the amount of impurities in the p-type pillar layers 23 in the device periphery region 107 is larger than the amount of impurities in the n-type pillar layers 13 in the device periphery region 107.

Now, an embodiment of the invention will be described with reference to the drawings. In the drawings shown below, identical portions are denoted by identical reference numerals. In the following description on the structure, a surface side of a semiconductor device provided with a gate electrode and a source electrode will be defined as an upside.

### EMBODIMENT

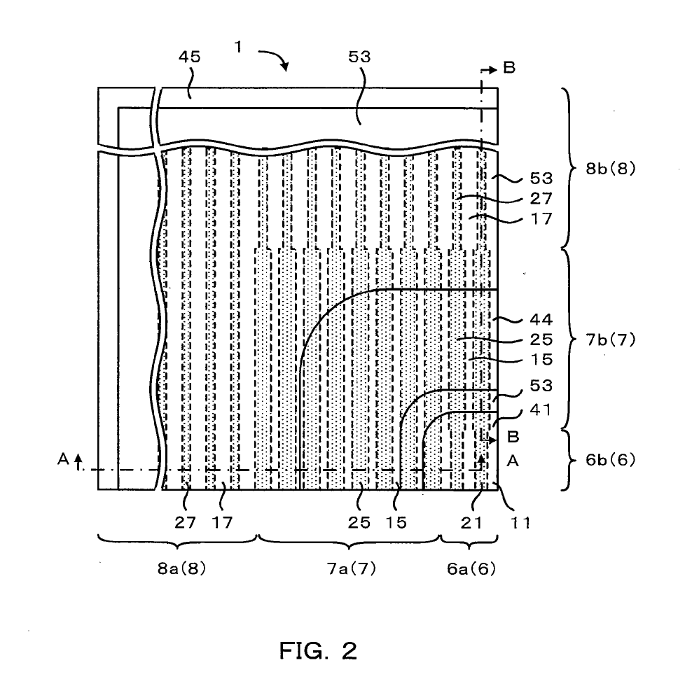

A semiconductor device according to an embodiment of the invention will be described with reference to FIG. 2 to FIG. 6.

As shown in FIG. 2, a semiconductor device 1 has a rectangular outline in a plan view and an upper left peripheral corner portion of the semiconductor device 1 is illustrated in FIG. 2. Overall, the semiconductor device 1 has boundaries of two substantially concentric rectangles located inside of the outline and the boundaries divide the semiconductor device 1 into three regions having different widths of pillar layers. The region located on the innermost side, i.e., a lower right side in FIG. 2, is a device region 6 (as indicated with reference numeral 6a in a horizontal axis direction and reference numeral 6b in a vertical axis direction), a region located outside the device region 6 is a first device periphery region 7 (as indicated with reference numeral 7a in the horizontal axis direction and reference numeral 7b in the vertical axis direction), and a region located outside the first device periphery region 7 is a second device periphery region 8 (as indicated with reference numeral 8a in the horizontal axis direction and reference numeral 8b in the vertical axis direction). In the following description, the regions will be referred to as the device region 6, the first device periphery region 7, and the second device periphery region 8, respectively, when there is no need to distinguish between the horizontal axis and the vertical axis.

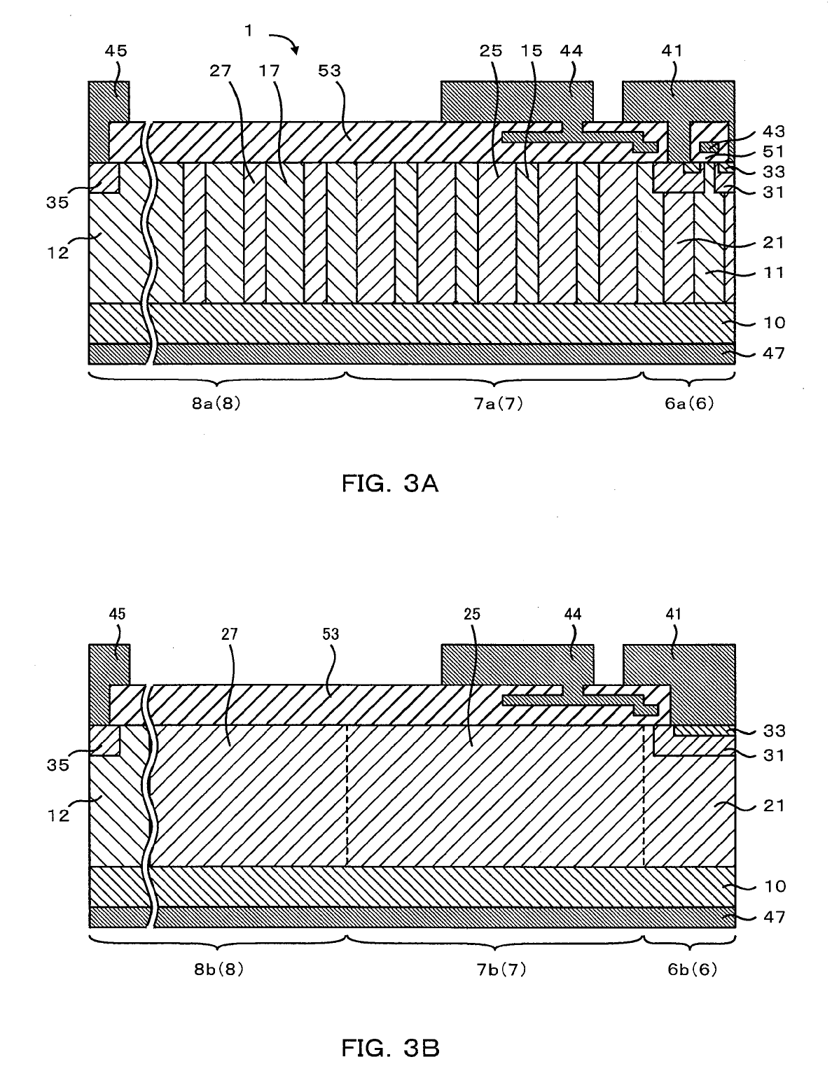

As shown in FIG. 2 to FIG. 3B, the semiconductor device 1 includes a vertical MOSFET in the device region 6, the vertical MOSFET having a SJ structure similar to the semiconductor device 106. An outer edge of the device region 6 and an outer edge of the first device periphery region 7, i.e., the boundary between the device region 6 and the first device periphery region 7 on a peripheral portion side are formed substantially parallel to an outer edge of the semiconductor device 1. An outer edge of a source electrode 41 serving as a second principal electrode has a rounded corner and is provided on an upper surface of the semiconductor device 1 along and outside of the outer edge of the device region 6. A field plate electrode 44 serving as an electrode layer has a rounded corner. The field plate electrode is located on the upper surface of the semiconductor device 1. The field plate electrode is provided outside of the source electrode 41 and along and inside of the outer edge of the first device periphery region 7.

As similar to the semiconductor device 101, the semiconductor device 1 includes a device region 6 as shown in FIG. 3. The device region 6 has an n⁺-type drain layer 10 being a first semiconductor layer having a first conductivity type, n-type pillar layers 11 being second conductive layers and p-type pillar layers 21 being third semiconductor layers having a second conductivity type which are formed on the n⁺-type drain layer 10 and are alternately arranged in a parallel direction to a surface of the n⁺-type drain layer 10, a drain electrode 47 serving as a first principal electrode being electrically connected to the n⁺-type drain layer 10, a p-type base layer 31 being an eighth semiconductor layer selectively formed in surfaces of the n-type pillar layers 11 and surfaces of the p-type pillar layers 21, an n⁺-type source layer 33 being a ninth semiconductor layer selectively formed in a surface of the p-type base layer 31, a source electrode 41 electrically connected to the p-type base layer 31 and the n⁺-type source layer 33, and a gate electrode 43 serving as a control electrode formed on the p-type base layer 31, the n⁺-type source layer 33, and the n-type pillar layers 11 with a gate insulating film 51 interposed in between.

The semiconductor device 1 further includes a first device periphery region 7 and a second device periphery region 8. The first device periphery region 7 is adjacent to the device region 6 and surrounds the device region 6. The first device periphery region 7 has n-type pillar layers 15 being fourth semiconductor layers and p-type pillar layers 25 being fifth semiconductor layers. The p-type pillar layers 25 have a larger amount of impurities than the n-type pillar layers 15. The layers 15 and the layers 25 are disposed on the n⁺-type drain layer 10 and arranged parallel to the n-type pillar layers 11 and the p-type pillar layers 21 in a way that the two different conductivity types are arranged by turns. The first device periphery region 7 also has a field plate electrode 44 disposed in the first device periphery region 7 and on sides of the n-type pillar layers 15 and the p-type pillar layers 25 opposite from the n⁺-type drain layer 10 with an interlayer insulating film 53 serving as an insulating film interposed in between. The second device periphery region 8 is adjacent to the first device periphery region 7 and surrounds the first device periphery region 7 The second device periphery region 8 has n-type pillar layers 17 being sixth semiconductor layers and p-type pillar layers 27 being seventh semiconductor layers. The p-type pillar layers 27 have a smaller amount of impurities than the n-type pillar layers 17. The n-type pillar layers 17 and the p-type pillar layers 27 are disposed on the n⁺-type drain layer 10 and arranged parallel to the n-type pillar layers 15 and the p-type pillar layers 25 in a way that the two different conductivity types are arranged by turns.

The semiconductor device 1 further includes an n-type semiconductor layer 12 located on the outer side (on the opposite side from the first device periphery region 7) of the n-type pillar layers 17 and the p-type pillar layers 27 which are alternately disposed, an n⁺-type channel stopper layer 35 located on a surface of the n-type semiconductor layer 12 on an outer peripheral portion near the interlayer insulating film 53, and an equipotential ring 45 located on the n⁺-type channel stopper layer 35.

The device region 6 is the region including a transistor. A drift layer in which a current flows in a vertical direction is formed of the n-type pillar layers 11 and the p-type pillar layers 21 which are formed into strip shapes and disposed in parallel. The drift layer extends in a perpendicular direction relative to a sheet surface of FIG. 3A (the direction of the vertical axis in FIG. 2, i.e., the direction along a B-B line). In the n-type pillar layers 11 and the p-type pillar layers 21 in FIG. 3A, the amounts of the corresponding n-type and p-type impurities are substantially equal to each other to achieve a good balance. Here, it is possible to dispose an n-type semiconductor layer (corresponding to the n-type semiconductor layer 12) having a similar impurity concentration to the n-type pillar layers 11 between an upper surface of the n+-type drain layer 10 and a lower surface of the p-type pillar layers 21. A similar configuration may also be employed in the first and second device periphery regions 7, 8.

The n-type pillar layers 15 and the p-type pillar layers 25 in the first device periphery region 7 are arranged from the device region 6 side to a position contacting the second device periphery region 8 so as to be parallel to the n-type pillar layers 11 and the p-type pillar layers 21. The n-type pillar layers 15 and the p-type pillar layers 25 are arranged alternately so as to be in conformity with the conductivity types of the n-type pillar layers 11 and the p-type pillar layers 21.

As shown in FIG. 2 and FIG. 3A, a pitch (a right-to-left direction on the sheet) between each n-type pillar layer 15 and each p-type pillar layer 25 in the direction of arrangement is equal to a pitch between each n-type pillar layer 11 and each p-type pillar layer 21 in the direction of arrangement. Although the width of the p-type pillar layers 25 is larger than the width of the p-type pillar layers 21, the width of the p-type pillar layers 25 may be either larger or smaller than the width of the pillar layers 21. The width of the n-type pillar layers 15 is smaller than the width of the p-type pillar layers 25. The SJ structure formed of the n-type pillar layers 15 and the p-type pillar layers 25 contains a larger amount of p-type impurities. Here, in order to improve the withstand voltage of the first device periphery region 7, the pitch between each n-type pillar layer 15 and each p-type pillar layer 25 in the direction of arrangement can be made smaller than the pitch between each n-type pillar layer 11 and each p-type pillar layer 21 in the direction of arrangement.

The field plate electrode 44 is connected to an electrode buried in the interlayer insulating film 53 and is disposed on the interlayer insulating film 53 along upper surfaces of the n-type pillar layers 15 and the p-type pillar layers 25. Although illustration is omitted, the field plate electrode 44 is connected to the gate electrode 43 on the interlayer insulating film 53. Here, the field plate electrode 44 may be connected to the source electrode 41 instead of the gate electrode 43. Meanwhile, the electrode buried in the interlayer insulating film 53 may be omitted.

A plan position on an end on the second device periphery region 8 side of the field plate electrode 44 does not exceed the first device periphery region 7 and is located on the device region 6 side of the boundary with the second device periphery region 8. The field plate electrode 44 may be disposed so as to protrude partially on top of or inside the interlayer insulating film 53 on the device region 6 side.

The n-type pillar layers 17 and the p-type pillar layers 27 in the second device periphery region 8 are arranged from the first device periphery region 7 side to a position on the opposite end side distant from the n⁺-type channel stopper layer 35 so as to be parallel to the n-type pillar layers 15 and the p-type pillar layers 25. The n-type pillar layers 17 and the p-type pillar layers 27 are arranged alternately so as to be in conformity with the conductivity types of the n-type pillar layers 15 and the p-type pillar layers 25. Here, the n-type pillar layers 17 and the p-type pillar layers 27 may be arranged to a position close to the n⁺-type channel stopper layer 35.

A pitch between each n-type pillar layer 17 and each p-type pillar layer 27 in the direction of arrangement is equal to the pitch between each n-type pillar layer 11 and each p-type pillar layer 21 in the direction of arrangement and to the pitch between each n-type pillar layer 15 and each p-type pillar layer 25 in the direction of arrangement. The width of the p-type pillar layers 27 is smaller than the width of the p-type pillar layers 25. The width of the n-type pillar layers 17 is larger than the width of the n-type pillar layers 15. For instance, the embodiment is the example in which the width of the p-type pillar layers 27 is smaller than the width of the n-type pillar layers 17. Accordingly, a drift layer formed of the n-type pillar layers 17 and the p-type pillar layers 27 of the embodiment contains a larger amount of n-type impurities. Here, in order to improve the withstand voltage of the second device periphery region 8, the pitch between each n-type pillar layer 17 and each p-type pillar layer 27 in the direction of arrangement can be made smaller than the pitch between each n-type pillar layer 11 and each p-type pillar layer 21 in the direction of arrangement.

Upper surfaces of the n-type pillar layers 17 and the p-type pillar layers 27 in the second device periphery region 8 are covered with the interlayer insulating film 53. The equipotential ring 45 is connected to the drain electrode 47, for example.

Each of the pillar layers has the following shape when taken along the line B-B. As shown in FIG. 2 and FIG. 3B, the p-type pillar layers 21, 25, 27 passing the device region 6 extend linearly in the direction along the line B-B through the device region 6b and the first and second device periphery regions 7b, 8b. Meanwhile, the pillar layers 25, 27 passing the first and second device periphery regions 7, 8 extend linearly through the first and second device periphery regions 7b, 8b. The pillar layer 27 passing only the second device periphery region 8 extends linearly through the second device periphery region 8b.

The widths of the p-type pillar layers 21, 25, 27 satisfy the above-described relations. Specifically, the width of the p-type pillar layers 25 is larger than the width of the p-type pillar layers 27. Meanwhile, the width of the p-type pillar layers 21 may be larger than the width of the p-type pillar layers 25, may be smaller than the width of the p-type pillar layers 27, or may be in between the width of the p-type pillar layers 25 and the width of the p-type pillar layers 27.

Since the n-type pillar layers 11, 15, 17 fill in spaces between the p-type pillar layers 21, 25, 27, the widths of the n-type pillar layers 11, 15, 17 are in a relationship equivalent to an inverted relationship among the p-type pillars 21, 25, 27. Specifically, the width of the n-type pillar layers 15 is smaller than the width of the p-type pillar layers 17. Meanwhile, the width of the n-type pillar layers 11 may be smaller than the width of the n-type pillar layers 15, may be smaller than the width of the n-type pillar layers 17, or may be in between the width of the n-type pillar layers 15 and the width of the n-type pillar layers 17. Here, it is also important that the width of the p-type pillar layers 25 is larger than the width of the n-type pillar layers 15 while the width of the p-type pillar layers 27 is smaller than the width of the n-type pillar layers 17.

The n⁺-type drain layer 10, the n-type pillar layers 11, 15, 17, the n-type semiconductor layer 12, the p-type pillar layers 21, 25, 27, the p-type base layer 31, the n⁺-type source layer 33, and the n⁺-type channel stopper layer 35 are made of single-crystal silicon, for example. Meanwhile, the gate insulating film 51 is made of a silicon oxide, the gate electrode 43 is made of polycrystalline silicon, and each of the source electrode 41, the field plate electrode 44, the equipotential ring 45, and the drain electrode 47 is made of metal.

Next, variations in the n-type pillar layers 11, 15, 17 and in the p-type pillar layers 21, 25, 27 occurring in the course of manufacturing the semiconductor device 1 will be described. The SJ structure of the semiconductor device 1 is fabricated in the following manner, for example. Specifically, a semiconductor layer serving as the n-type pillar layers 11, 15, 17 is formed, then trenches serving as the p-type pillar layers 21, 25, 27 are formed, and then the trenches are filled with a semiconductor layer doped with p-type impurities. The trenches are processed in accordance with a reactive ion etching (RIE) method, for example, by use of a mask formed so as to have desired aperture dimensions in accordance with a photolithography method. Although the p-type pillar layers 21, 25, 27 illustrated have rectangular cross sections, there may also be other modifications as shown in modifications to be described later, as in a case where the dimension on the upper side is different from the dimension on the lower (bottom) side and a case where a central portion has a different dimension attributable to various process conditions.

As shown in FIG. 3A, when the process variations are suppressed, the dimensions and the shapes substantially the same as the designed structure are achieved. When filling variations are also suppressed, the p-type pillar layers 21, 25, 27 having the amounts of impurities substantially equal to designed values are formed as a consequence.

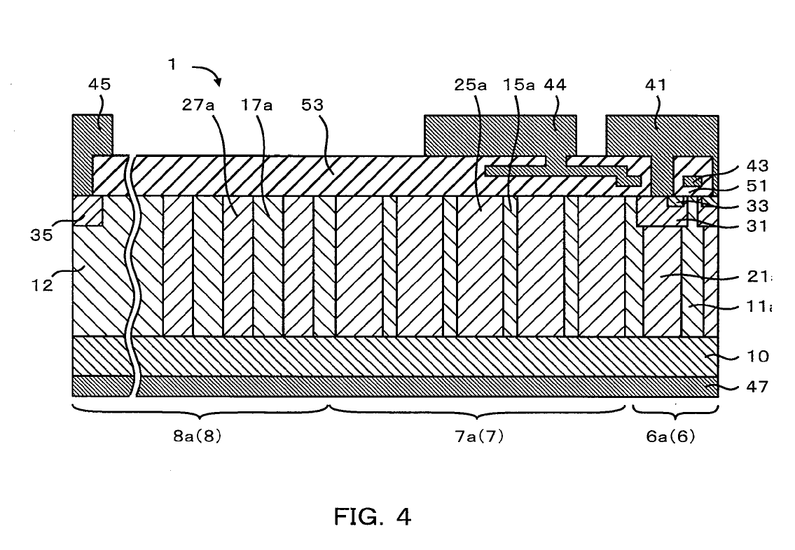

As shown in FIG. 4, when a variation occurs and the amount of p-type impurities is increased, the aperture dimensions of the trenches become larger than the designed structure, for example. Accordingly, if the trenches are filled with the semiconductor layer having substantially the same impurity concentration as the designed value, p-type pillar layers 21a, 25a, 27a containing increased amounts of the impurities on the whole are formed. Since the pitch in the direction of arrangement is constant, the amounts of impurities in n-type pillar layers 11a, 15a, 17a are relatively reduced. Here, the amount of impurities in the p-type pillar layer 27a in the second device periphery region 8 located close to the n⁺-type channel stopper layer 35 is not increased so much as to cause electrical field concentration.

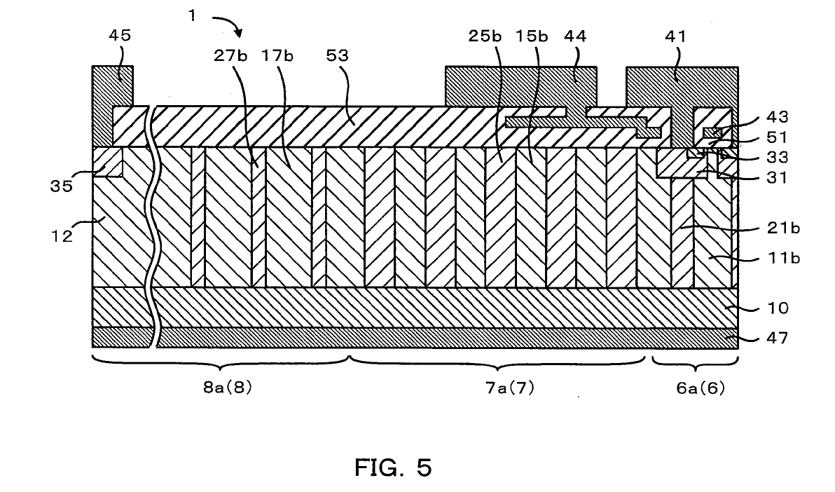

Meanwhile, as shown in FIG. 5, when a variation occurs and the amount of p-type impurities is decreased, the aperture dimensions of the trenches become smaller than the designed structure, for example. Accordingly, if the trenches are filled with the semiconductor layer having substantially the same impurity concentration as the designed value, p-type pillar layers 21b, 25b, 27b containing decreased amounts of the impurities on the whole are formed. Since the pitch in the direction of arrangement is constant, the amounts of impurities in n-type pillar layers 11b, 15b, 17b are relatively increased. Here, the amount of impurities in the p-type pillar layer 25b in the first device periphery region 7 located below the field plate electrode 44 is not increased so much as to cause electrical field concentration.

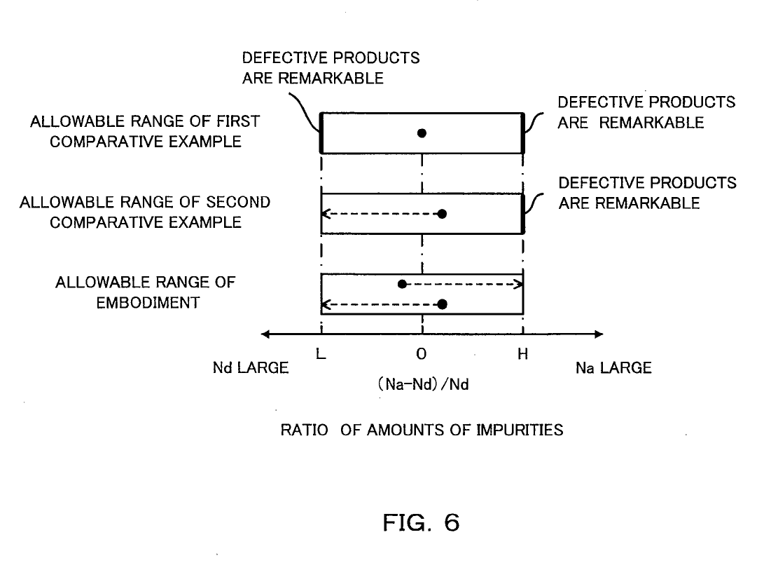

Next, a reason why it is possible to increase the number of non-defective products while ensuring withstand voltages will be described. In FIG. 6, the, horizontal axis indicates a ratio (a ratio of amounts of impurities) of a difference (Na−Nd) to Nd, where Na is the amount of impurities in the p-type pillar layers 23, 25, 27 and Nd is the amount of impurities in the n-type pillar layers 13, 15, 17

As shown in FIG. 6, when a reference value of a withstand voltage is defined as VB, an allowable range of the ratio of amounts of impurities which can ensure a withstand voltage of the semiconductor device 1 falls within a range between a ratio L of the amounts of impurities where the amounts of impurities (Na) in the p-type pillar layers 25, 27 are small and a ratio H where the amounts of impurities in the p-type pillar layers 25, 27 are large.

In the designed structure of the semiconductor device 101 of the first comparative example, the amounts of impurities are balanced, i.e., the ratio of the amounts of impurities is zero. When the ratio of the amounts of impurities is set taking a variation due to a manufacturing process into consideration, withstand voltage defects on the device region 6 side in the device periphery region 107, i.e., in a breakdown region 61 and withstand voltage defects on the equipotential ring 45 side, i.e. in a breakdown region 63 are remarkable. That is, as shown in a top part of FIG. 6, the withstand voltage defects are remarkable in the p-type pillar layers 23 at portions where the amount of impurities is low and where the amount of impurities is high.

Meanwhile, according to the designed structure of the semiconductor device of the second comparative example, when the ratio of the amounts of impurities is set taking the variation due to the manufacturing process into account, withstand voltage defects on the n⁺-type channel stopper layer 35 in the device periphery region 107, i.e., in the breakdown region 63 are relatively increased. That is, as shown in a middle part of FIG. 6, the withstand voltage defects are remarkable when the amount of impurities is high in the p-type pillar layers 23. To put it the other way around, the allowable range is expanded to the side where the amount of impurities is low in the p-type pillar layers 23 (as indicated with an arrow in a dotted line)).

Meanwhile, as described previously, the semiconductor device 1 is configured so that the p-type pillar layers 25 has a larger amount of impurities than the n-type pillar layers 15 in the first device periphery region 7, and that the p-type pillar layers 27 has a smaller amount of impurities than the n-type pillar layers 17 in the second device periphery region 8. As a result, as shown in a bottom part of FIG. 6, when taking into consideration the variations due to the manufacturing process as similar to the first and second comparative examples, it is possible to expand the allowable range toward a portion where the amount of impurities in the p-type pillar layers 25 is low and to expand the allowable range toward a portion where the amount of impurities in the p-type pillar layers 27 is high. The allowable range defined by the ratio L of the amounts of impurities and the ratio H of the amounts of impurities remains unchanged after all, but as a consequence, it is possible to ensure a larger number of non-defective products surpassing the reference value VB of the withstand voltage.

Further, the reason for the increase in the number of non-defective products with ensured withstand voltages will be described as follows. In the semiconductor device 101 of the first comparative example, the increase in the ratio of amounts of p-type impurities causes the increase in the amounts of impurities in the p-type pillar layers 23, which leads to occurrence of local electrical field concentration in the vicinity of an interface (the breakdown region 63) between the interlayer insulating film 53 and the p-type pillar layer 23 located closest to the equipotential ring 45 side. Meanwhile, in the semiconductor device 1 of the embodiment, the width of the p-type pillar layers 27 in the breakdown region 63 is reduced in advance, i.e., the amounts of n-type impurities are increased in advance. Accordingly, extension of a depletion layer is suppressed and the local electrical field concentration is less likely to occur even when the ratio of the amounts of p-type impurities is increased.

On the other hand, in the semiconductor device 101, the increase in the ratio of amounts of n-type impurities causes the increase in the amounts of impurities in the n-type pillar layers 13, which leads to occurrence of local electrical field concentration on a portion near an end on the equipotential ring 45 side of the field plate electrode 44 and in the vicinity of an interface (the breakdown region 61) between the interlayer insulating film 53 and the n-type and p-type pillar layers 13, 23. Meanwhile, in the semiconductor device 1 of the embodiment, the width of the n-type pillar layers 15 in the breakdown region 61 is reduced in advance, i.e., the amounts of p-type impurities are increased in advance. Accordingly, a depletion layer tends to extend outward even when the ratio of the amounts of n-type impurities is increased. Hence the local electrical field concentration is less likely to occur.

As a consequence, more non-defective products for the semiconductor device 1 having certain withstand voltages can be ensured even though the amounts of impurities in the n-type pillar layers 15, 17 and in the p-type pillar layers 25, 27 are varied to the same degree as in the first and second comparative examples. Moreover, it is possible to suppress a drop in a yield rate while maintaining a constant withstand voltage even if the amounts of impurities are varied further. That is, more non-defective products for the semiconductor device 1 that satisfy the withstand voltage standard can be achieved even when the products have the variations in the widths, the impurity concentrations, and the like among the n-type pillar layers 15, 17 and in the p-type pillar layers 25, 27 caused in the manufacturing process to the same degree as the first and second comparative examples. Hence, it is possible to say that the semiconductor device 1 has the structure which is resistant to the variations in the manufacturing process.

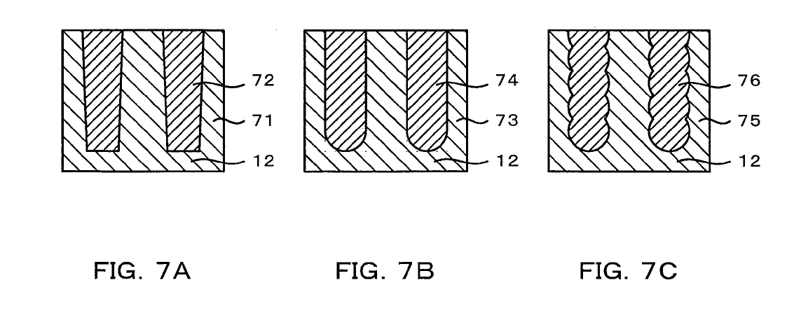

Next, a first modification of the embodiment will be described with reference to FIGS. 7A to 7C. The first modification is different from the semiconductor device 1 of the embodiment in that the pillar layers have cross-sectional shapes other than the rectangle. Portions of the first modification identical to the portions of the embodiment will be denoted by identical reference numerals and description of such identical portions will be omitted.

As shown in FIGS. 7A to 7C, in place of the rectangular pillar layers 21, 25, 27 (see FIG. 3A) of the semiconductor device 1 of the embodiment, the p-type pillar layers of the semiconductor device of the first modification have different cross sections as represented by p-type pillar layers 72 of a trapezoidal shape having a larger width on a source electrode side and a smaller width on a drain electrode side, or by p-type pillar layers 74 of a shape having a bottom surface on the drain electrode side which is a curved face protruding toward the drain electrode, or by p-type pillar layers 76 of a shape provided with corrugated wall surface extending from the source electrode side toward the drain electrode side. Here, FIGS. 7A and 7B are the examples schematically showing the structures that are to appear when fabricating the p-type pillar layers 72, 74 in accordance with the trench filling method. Meanwhile, FIG. 7C is the example schematically showing the structure that is to appear when fabricating the p-type pillar layers 76 in accordance with a method of repeating ion implantation and buried growth.

N-type pillar layers 71, 73 or 75 which are disposed alternately with the p-type pillar layers 72, 74 or 76 of the first modification are formed so as to fill in the spaces between each corresponding two p-type pillar layers. An n-type semiconductor layer 12 having a similar impurity concentration as the impurity concentrations of the n-type pillar layers 71, 73 or 75 is provided on the drain electrode sides of the p-type pillar layers 72, 74 or 76 of the first modification. Here, the n-type semiconductor layer 12 may be omitted as similar to the semiconductor device 1 of the embodiment. Except for the different cross sectional shapes of the p-type pillar layers 72, 74, 76 and the n-type pillar layers 71, 73, 75, the semiconductor device of the first modification has similar configurations as the semiconductor device 1 of the embodiment.

The semiconductor device of the first modification is similar to the semiconductor device 1 of the embodiment in the relationship of the amounts of impurities and thus has similar effects to the effects of the semiconductor device 1.

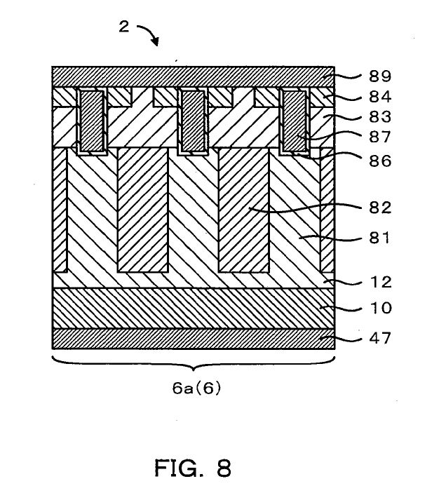

Next, a second modification of the embodiment will be described with reference to FIG. 8. The second modification is different from the semiconductor device 1 of the embodiment in that the gate electrode has a trench structure. Portions of the second modification identical to the portions of the embodiment will be denoted by identical reference numerals and description of such identical portions will be omitted.

As shown in FIG. 8, in a semiconductor device 2, n-type pillar layers 81 and p-type pillar layers 82 are provided in the device region 6 in place of the n-type pillar layers 11 and the p-type pillar layers 21 of the semiconductor device 1. The n-type semiconductor layer 12 having a similar configuration to the n-type pillar layers 81 is provided to sides of the p-type pillar layers 82 close to the n⁺-type drain layer 10. A p-type base layer 83 is provided on the n-type pillar layers 81 and the p-type pillar layers 82, and an n⁺-type source layer 84 is formed selectively in the p-type base layer 83. Gate electrodes 87 covered with a gate insulating film 86 are provided so as to penetrate the n⁺-type source layer 84 and the p-type base layer 83 and to reach the n-type pillar layers 81. The p-type base layer 83 and the n⁺-type source layer 84 are electrically connected to the source electrode 89. The semiconductor device 2 has a similar structure on a rear surface (the drain electrode) side as the semiconductor device 1. Although illustration is omitted, the first and second device periphery regions 7, 8 having the similar SJ structure as the semiconductor device 1 are provided outside the device region 6.

The semiconductor device 2 has an effect similar to a vertical-type MOSFET provided with a gate electrode of the trench structure. In addition, the semiconductor device 2 has the effect of the semiconductor device 1 of the embodiment, specifically, the effect to suppress a drop in the yield rate of non-defective products having certain withstand voltages even if the amount of impurities varies largely.

The invention is not limited only to the above-described embodiment and various other modifications are possible without departing from the scope of the invention.

For example, the embodiment has been described by use of the example of a termination structure configured to form the field plate electrode in the first device periphery region (the termination region). However, in addition to the field plate electrode, it is also possible to form another termination structure including at least one of a p-type reduced surface field (RESURF) layer or a p-type guard ring layer located between the interlayer insulating film and each of the n-type pillar layers and the p-type pillar layers in the first device periphery region.

Moreover, the embodiment has been described by use of the example where the amounts of impurities are varied by changing the widths of the n-type pillar layers and the p-type pillar layers. However, it is needless to say that the amounts of impurities may be changed by changing the impurity concentrations, by changing the pitch in the direction of arrangement, or by changing a combination of the widths, the pitch in the direction of arrangement, and the impurity concentrations.

Moreover, the embodiment has been described by use of the example where the n-type pillar layers and the p-type pillar layers having the strip shapes are arranged in parallel to each other. However, instead of the strip shapes, various other patterns may be employed including a lattice pattern, a dot pattern, and the like in plan views.

Moreover, the embodiment has been described by defining the first conductivity type as the n-type while defining the second conductivity type as the p-type. However, it can also be applicable that the first and the second conductivity types are the p-type and the n-type.

Moreover, the embodiment has been described by use of the example where the first and second device periphery regions are applied to the vertical-type MOSFET having the super junction structure. However, the first and second device periphery regions are also applied to other semiconductor devices having the super junction structure, such as an insulated gate bipolar transistor (IGBT), for example.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device comprising:
a transistor containing a first semiconductor layer of a first conductivity type and a drift layer formed in a device region on the first semiconductor layer, the drift layer having a pillar structure in which a second semiconductor layer of the first conductivity type and a third semiconductor layer of a second conductivity type are alternately disposed in a direction parallel to a surface of the first semiconductor layer;
a fourth semiconductor layer of the first conductivity type and a fifth semiconductor layer of the second conductivity type formed in a first device periphery region on the first semiconductor layer, the first device periphery region being adjacent to the device region and surrounding the device region, the fourth and the fifth semiconductor layers being alternately disposed and parallel to the drift layer, the fifth semiconductor layer having a larger amount of impurities than the fourth semiconductor layer;
an electrode layer formed on the fourth and the fifth semiconductor layers with an insulating film interposed in between; and
a sixth semiconductor layer of the first conductivity type and a seventh semiconductor layer of the second conductivity type formed in a second device periphery region on the first semiconductor layer, the second device periphery region being adjacent to the first device periphery region and surrounding the first device periphery region, the sixth and the seventh semiconductor layers being alternately disposed and parallel to the fourth and the fifth semiconductor layers, the seventh semiconductor layer having a smaller amount of impurities than the sixth semiconductor layer.

2. the semiconductor device according to claim 1, wherein the transistor includes:
an eighth semiconductor layer of the second conductivity type selectively formed on a surface of the second and the third semiconductor layers;
a ninth semiconductor layer of the first conductivity type selectively formed on a surface of the eighth semiconductor layer;
a gate insulating film formed on the eighth, the ninth and the second semiconductor layers;
a control electrode formed on the gate insulating film and isolated from the eighth, the ninth and the second semiconductor layers;
a first principal electrode electrically connected to the first semiconductor layer; and
a second principal electrode electrically connected to the eighth and the ninth semiconductor layers.

3. the semiconductor device according to claim 1, wherein a pitch between the fourth and the fifth semiconductor layers in the direction of arrangement and a pitch between the sixth and the seventh semiconductor layers in the direction of arrangement are the same as a pitch between the second and the third semiconductor layers in the direction of arrangement.

4. the semiconductor device according to claim 2, wherein a pitch between the fourth and the fifth semiconductor layers in the direction of arrangement and a pitch between the sixth and the seventh semiconductor layers in the direction of arrangement are the same as a pitch between the second and the third semiconductor layers in the direction of arrangement.

5. the semiconductor device according to claim 1, wherein the second, the fourth, the sixth, the third, the fifth and the seventh semiconductor layers have substantially the same concentrations of impurities in spite of the difference of the conductivity type.

6. the semiconductor device according to claim 2, wherein the second, the fourth, the sixth, the third, the fifth and the seventh semiconductor layers have substantially the same concentrations of impurities in spite of the difference of the conductivity type.

7. the semiconductor device according to claim 3, wherein the second, the fourth, the sixth, the third, the fifth and the seventh semiconductor layers have substantially the same concentrations of impurities in spite of the difference of the conductivity type.

8. the semiconductor device according to claim 1, wherein the second semiconductor layer of the first conductivity type and the third semiconductor layer of the second conductivity type have substantially the same amounts of impurities.

9. the semiconductor device according to claim 2, wherein the second semiconductor layer of the first conductivity type and the third semiconductor layer of the second conductivity type have substantially the same amounts of impurities.

10. the semiconductor device according to claim 3, wherein the second semiconductor layer of the first conductivity type and the third semiconductor layer of the second conductivity type have substantially the same amounts of impurities.

11. the semiconductor device according to claim 4, wherein the second semiconductor layer of the first conductivity type and the third semiconductor layer of the second conductivity type have substantially the same amounts of impurities.

12. the semiconductor device according to claim 1, wherein the sixth semiconductor layer has the higher concentration of impurities than the fourth semiconductor layer and the same width in the direction of arrangement as the fourth semiconductor layer, the seventh semiconductor layer has the lower concentration of impurities than the fifth semiconductor layer and the same width in the direction of arrangement as the fifth semiconductor layer.

13. the semiconductor device according to claim 1, wherein the impurity concentrations of the fourth and the fifth semiconductor layers and the impurity concentrations of the sixth and the seventh semiconductor layers are lower than the impurity concentrations of the second and the third semiconductor layers.

14. the semiconductor device according to claim 1, wherein at least one of a reduced surface field (RESURF) layer of the first conductivity type or a guard ring layer of the first conductivity type is formed between the insulating film and each of the fourth and the fifth semiconductor layers in the first device periphery region.

15. the semiconductor device according to claim 1, wherein a channel stopper layer of the first conductivity type which has a higher impurity concentration than the second semiconductor layer is disposed on the opposite side from the first device periphery region in the second device periphery region.

16. A semiconductor device comprising:
a transistor containing a first semiconductor layer of a first conductivity type and a drift layer formed in a device region on the first semiconductor layer, the drift layer having a pillar structure in which a second semiconductor layer of the first conductivity type and a third semiconductor layer of a second conductivity type are alternately disposed in a direction parallel to a surface of the first semiconductor layer;
a fourth semiconductor layer of the first conductivity type and a fifth semiconductor layer of the second conductivity type formed in a first device periphery region on the first semiconductor layer, the first device periphery region being adjacent to the device region and surrounding the device region, the fourth and the fifth semiconductor layers being alternately disposed and parallel to the drift layer, the fifth semiconductor layer having a larger amount of impurities than the fourth semiconductor layer;
an electrode layer formed on the fourth and the fifth semiconductor layers with an insulating film interposed in between;
a sixth semiconductor layer of the first conductivity type and a seventh semiconductor layer of the second conductivity type formed in a second device periphery region on the first semiconductor layer, the second device periphery region being adjacent to the first device periphery region and surrounding the first device periphery region, the sixth and the seventh semiconductor layers being alternately disposed and parallel to the fourth and the fifth semiconductor layers, the seventh semiconductor layer having a smaller amount of impurities than the sixth semiconductor layer;
an eighth semiconductor layer of the second conductivity type selectively formed on a surface of the second and the third semiconductor layers;
a ninth semiconductor layer of the first conductivity type selectively formed on a surface of the eighth semiconductor layer;
a gate insulating film formed on the eighth, the ninth and the second semiconductor layers;
a control electrode formed on the gate insulating film and isolated from the eighth, the ninth and the second semiconductor layers;
a first principal electrode electrically connected to the first semiconductor layer; and
a second principal electrode electrically connected to the eighth and the ninth semiconductor layers.

17. the semiconductor device according to claim 16, wherein a pitch between the fourth and the fifth semiconductor layers in the direction of arrangement and a pitch between the sixth and the seventh semiconductor layers in the direction of arrangement are the same as a pitch between the second and the third semiconductor layers in the direction of arrangement.

18. the semiconductor device according to claim 16, wherein the second, the fourth, the sixth, the third, the fifth and the seventh semiconductor layers have substantially the same concentrations of impurities in spite of the difference of the conductivity type.

19. the semiconductor device according to claim 16, wherein the second semiconductor layer of the first conductivity type and the third semiconductor layer of the second conductivity type have substantially the same amounts of impurities.
